(19) United States
(12) Patent Application Publication
(10) Pub. No.: US 2023/0062863 A1
(43) Pub. Date: Mar. 2, 2023

(54) METHOD FOR MANUFACTURING LAMINATE

(71) Applicant: SHOWA DENKO K. K., Tokyo (JP)

(72) Inventors: Sho TONEGAWA, Ichihara-shi (JP); Akira SAKAWAKI, Ichihara-shi (JP); Daizo ENDO, Ichihara-shi (JP); Kota HASEGAWA, Ichihara-shi (JP)

(73) Assignee: SHOWA DENKO K. K., Tokyo (JP)

(21) Appl. No.: 17/587,196

(22) Filed: Jan. 28, 2022

(30) Foreign Application Priority Data
Aug. 20, 2021 (JP) 2021-135109

(51) Int. Cl. H01L 41/314; H01L 41/187; H01L 41/29

(52) U.S. Cl. CPC H01L 41/314; H01L 41/187; H01L 41/29

(57) ABSTRACT

A method for manufacturing an AlN-based laminate includes: forming on or above a substrate 210 a single-crystalline electrode layer 230 containing a metal element; and forming an AlN-based piezoelectric layer 240 on the electrode layer 230 by sputtering. Forming the piezoelectric layer 240 includes applying a pulse voltage to a target during the sputtering at a duty ratio of not more than 4% and at an average power density during pulse application of from 200 W/cm² to 2500 W/cm².

### CROSS REFERENCE TO RELATED APPLICATIONS

This application is based on and claims priority under 35 USC § 119 to Japanese Patent Application No. 2021-135109 filed on Aug. 20, 2021, the disclosure is incorporated herein by reference in its entirety.

### BACKGROUND

### Technical Field

The present invention relates to a method for manufacturing a laminate.

### Related Art

For example, for communications using mobiles phones or smartphones, it is necessary to extract radio waves of desired frequencies using a filter, from among radio waves received at an antenna. One example of such filters is a filter using a resonator. For example, the resonator has a structure including a laminate that is composed of an electrode and a piezoelectric layer made of a piezoelectric body laminated on the electrode.

Previous publications in the art disclose a piezoelectric thin film that includes an aluminum nitride thin film containing scandium, wherein a content of scandium in the aluminum nitride thin film is from 0.5 to 50 atomic %, based on a total of the number of scandium atoms and the number of aluminum atoms being taken as 100 atomic % (see Patent Document 1).

Previous publications in the art also disclose a method for manufacturing a piezoelectric thin film that includes an aluminum nitride thin film containing scandium, the method including a sputtering step of sputtering aluminum and scandium under an atmosphere containing at least a nitrogen gas. The sputtering step of this method performs sputtering at a substrate temperature in a range from 5° C. to 450° C. such that a content of scandium falls within a range from 0.5 to 50 atomic % (see Patent Document 2).

Previous publications in the art also disclose a piezoelectric thin film made of scandium aluminum nitride and obtained by sputtering, wherein a content of carbon atoms is not more than 2.5 atomic %. The method for manufacturing this piezoelectric thin film includes sputtering scandium and aluminum onto a substrate concurrently from a scandium aluminum alloy target material under an atmosphere containing at least a nitrogen gas, the target material having a carbon atomic content of not more than 5 atomic (see Patent Document 3).

### CITATION LIST

### Patent Literature

Patent Document 1: Japanese Patent Application Laid-Open Publication No. 2009-010926

Patent Document 2: Japanese Patent Application Laid-Open Publication No. 2011-015148

Patent Document 3: Japanese Patent Application Laid-Open Publication No. 2014-236051

### SUMMARY

A recent ever-increasing volume of communications often leads to congestion. To deal with this issue, various advancements have been made including enabling faster communications through higher frequencies and increasing the capacity with wider bandwidths, as well as employing multiple communication bands.

In this case, a high Q value is required for a laminate to prevent interference with an adjacent band and facilitate low-loss characteristics. The laminate is also required to be adapted to a wider bandwidth to meet radio frequency standards. To achieve required characteristics for both of the Q value and the bandwidth, improving crystallinity of the laminate is desired.

It is an object of certain embodiments of the present invention to provide a method for manufacturing a laminate having high crystallinity.

Accordingly, certain embodiments of the present invention provide a method for manufacturing an AlN-based laminate. The method includes: forming on or above a substrate a single-crystalline electrode layer containing a metal element; and forming an AlN-based piezoelectric layer on the electrode layer by sputtering. Forming the piezoelectric layer includes applying a pulse voltage to a target during the sputtering at a duty ratio of not more than 4% and at an average power density during pulse application of from 200 W/cm² to 2500 W/cm².

The duty ratio may be not more than 2% during the sputtering.

The piezoelectric layer may contain Sc.

A content of Sc in the piezoelectric layer may be not more than 50 atomic %, based on a total of the number of Sc atoms and the number of Al atoms in the piezoelectric layer being taken as 100 atomic %.

The piezoelectric layer may be formed using a target containing Al and Sc.

The piezoelectric layer may be formed on an entire surface of the electrode layer.

The electrode layer may have a composition including at least one substance selected from Co, Cu, Ru, Pt, Al, Au, Ag, Mo, W, ZrN, and Ti.

The substrate may have any composition selected from sapphire, Si, quartz, SrTiO₃, LiTaO₃, LiNbO₃, and SiC.

The electrode layer with the piezoelectric layer laminated thereon may be released from the substrate.

Certain embodiments of the present invention can provide a method for manufacturing a laminate having high crystallinity.

### BRIEF DESCRIPTION OF THE DRAWINGS

Exemplary embodiments of the present invention will be described in detail based on the following figures, wherein:

FIG. 1 shows a resonator according to an embodiment;

FIG. 2 shows a laminate for fabricating a piezoelectric layer;

FIG. 3 shows a Hi-pulse sputtering method;

FIG. 4A shows a result of out of plane X-ray rocking curve (XRC) measurement for AlN according to the embodiment;

FIG. 4B shows a result of in-plane XRC measurement for AlN according to the embodiment;

FIG. 4C shows a cross-sectional transmission electron microscope (TEM) image of AlN according to the embodiment;

FIG. 5 is a flowchart of a method for manufacturing the laminate;

FIG. 6 shows a buffer layer, an electrode layer, and a piezoelectric layer deposited;

FIG. 7A shows a TEM image of AlN according to the embodiment;

FIG. 7B shows an electron diffraction pattern of AlN according to the embodiment;

FIG. 7C shows a TEM image of Sc_{0.2}Al_{0.8}N according to the embodiment;

FIG. 7D shows an electron diffraction pattern of Sc_{0.2}Al_{0.8}N according to the embodiment;

FIG. 7E shows a TEM image of polycrystalline AlN;

FIG. 7F shows an electron diffraction pattern of polycrystalline AlN;

FIGS. 8A-8E each show an interatomic distance x used to calculate a lattice mismatch;

FIG. 9 is a table showing specific examples of lattice mismatches between a lower electrode layer and a piezoelectric layer; and

FIGS. 10A to 10F show a method for manufacturing the resonator.

### DETAILED DESCRIPTION

An embodiment of the present invention will be described below with reference to the attached drawings.

### <Overall Description of a Resonator 100>

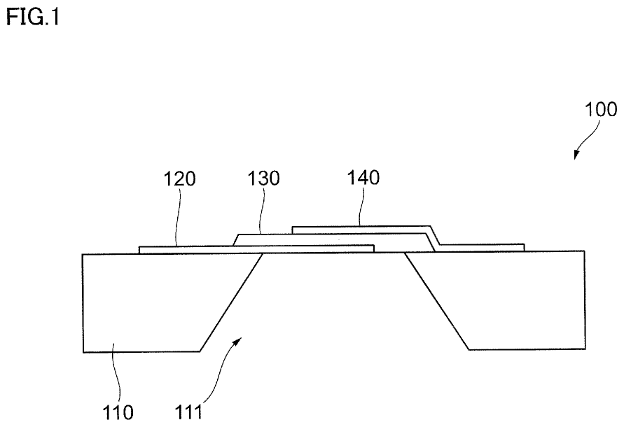

FIG. 1 shows a resonator 100 according to an embodiment.

The resonator 100 as shown includes a substrate 110 as a support body, a lower electrode layer 120 as an electrode formed on a lower side, a piezoelectric layer 130 made of a piezoelectric body, and an upper electrode layer 140 as an electrode formed on an upper side. The substrate 110, the lower electrode layer 120, the piezoelectric layer 130, and the upper electrode layer 140 are laminated in this order from bottom to top. It should be noted that any terms of orientation such as “lower,” “upper,” “top,” and “bottom” are used to indicate orientations of these layers in the figures for purposes of conveniently illustrating how they are laminated. As such, these layers are not necessarily oriented as shown when the resonator 100 is actually used.

The substrate 110 is a support substrate to support the lower electrode layer 120, the piezoelectric layer 130, and the upper electrode layer 140. This support substrate is different from a substrate for the growing of a thin film of the piezoelectric layer 130. In the present embodiment, a single-crystalline substrate, such as a silicon (Si) substrate for example, is used for the substrate 110. The substrate 110 includes a cavity 111 in its lower portion.

The lower electrode layer 120 is formed on the substrate 110. The material of the lower electrode layer 120 is not particularly limited; for example, the lower electrode layer 120 may be made of ruthenium (Ru), gold (Au), silver (Ag), copper (Cu), platinum (Pt), aluminum (Al), molybdenum (Mo), tungsten (W), and the like.

The piezoelectric layer 130 is formed on the lower electrode layer 120 and made of a piezoelectric body. Radio waves of desired frequencies are selectively extracted using a piezoelectric effect provided by the piezoelectric body.

The upper electrode layer 140, which is an example of the electrode layer, is formed on the piezoelectric layer 130. The upper electrode layer 140 has a single-crystalline structure containing a metal element. The upper electrode layer 140 may be made of the same metal as that of the lower electrode layer 120.

That is, the resonator 100 has a structure in which the piezoelectric layer 130 is sandwiched between the lower electrode layer 120 and the upper electrode layer 140. For example, the lower electrode layer 120, the piezoelectric layer 130, and the upper electrode layer 140 may be formed by sputtering.

When the resonator 100 is used as a high-frequency bandpass filter, it is required to ensure both a high Q value and a wide bandwidth. The Q value is a quality factor, representing sharpness of selectable frequencies. A high Q value corresponds to excellent steepness for preventing interference with adjacent frequency bands, as well as excellent low-loss characteristics. The bandwidth is a width of selectable frequencies, which is defined as a difference between highest and lowest frequencies of radio waves that can pass through the bandpass filter. Covering a wide bandwidth further facilitates meeting frequency standards of devices that use the filter. The bandwidth is proportional to an electromechanical coupling coefficient k² of the piezoelectric body constituting the piezoelectric layer 130. The electromechanical coupling coefficient k² is a quantity that represents the efficiency of the piezoelectric effect. A higher Q value and a higher electromechanical coupling coefficient k² are preferred.

The product of the above two parameters, namely k²Q can be viewed as a performance index of the bandpass filter. The value of k²Q depends on the characteristics of the piezoelectric body constituting the piezoelectric layer 130. Some previous approaches have attempted to use, for example, AlN or ScAlN for the piezoelectric body. However, AlN as used in previous approaches is unable to cover a sufficient bandwidth. Also, ScAlN as used in previous approaches increases the bandwidth but reduces the Q value. That is, bandpass filters of previous approaches are based on polycrystals, which makes it difficult to ensure both a wide bandwidth and a high Q value.

The piezoelectric layer 130 of the present embodiment is single-crystalline, so that one can expect to obtain a wide bandwidth as well as a high Q value by using the resonator 100 as a bandpass filter. In other words, it can be expected that both a high Q value and a wide bandwidth are ensured.

### <Laminate Fabricated for Forming the Piezoelectric Layer 130>

Now a description will be given of a laminate for fabricating the single-crystalline piezoelectric layer 130.

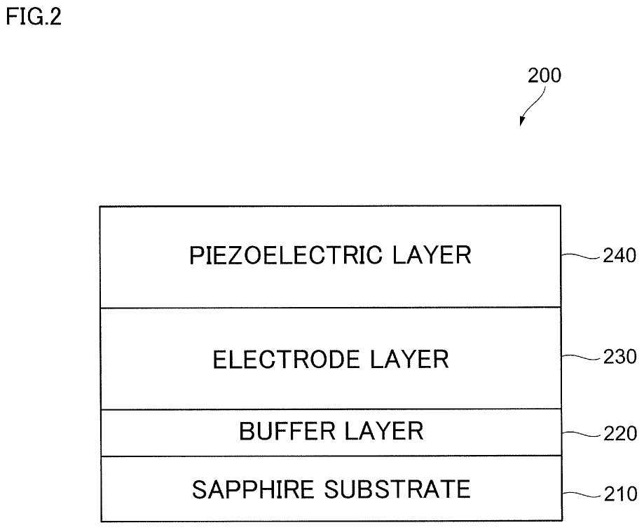

FIG. 2 shows a laminate 200 for fabricating the piezoelectric layer 130.

The laminate 200 as shown includes a substrate 210, a buffer layer 220 as an intermediate layer, an electrode layer 230 serving as an electrode, and a piezoelectric layer 240 made of a piezoelectric body.

The substrate 210 is a growth substrate on which the buffer layer 220, the electrode layer 230, and the piezoelectric layer 240 are grown as thin films by sputtering. For this reason, a single-crystalline substrate is used for the substrate 210.

The buffer layer 220 is an intermediate layer formed between the substrate 210 and the electrode layer 230 to improve the crystal orientation of the electrode layer 230.

The electrode layer 230 corresponds to the upper electrode layer 140 in the resonator 100 of FIG. 1. Thus, the electrode layer 230 has a single-crystalline structure containing a metal element.

The piezoelectric layer 240 corresponds to the piezoelectric layer 130 in the resonator 100 of FIG. 1. The piezoelectric layer 240 is formed on the electrode layer 230 and made of a piezoelectric body.

In the present embodiment, the buffer layer 220 and the piezoelectric layer 240 are AlN-based single-crystalline layers. The term “AlN-based” or “based on AlN” means containing AlN at a molar ratio of 50% or more. The buffer layer 220 and the piezoelectric layer 240 may be based on ScAlN single crystals, instead of AlN single crystals. The buffer layer 220, the electrode layer 230, and the piezoelectric layer 240 are detailed in subsequent paragraphs.

In the present embodiment, the buffer layer 220 and the piezoelectric layer 240 are based on single crystals having a composition of either AlN or ScAlN. ScAlN can be viewed as a composition that is obtained by substituting Al in AlN with Sc. Thus, ScAlN can also be denoted as ScₓAl_{y}N (x+y=1), where x is preferably from 0 to 0.5, and y is preferably from 0.5 to 1.0. If x is more than 0.5, it would change the crystal system of ScAlN and degrade the piezoelectricity. In the context of increasing the crystallinity, x is preferably from 0.005 to 0.35, and y is preferably from 0.65 to 0.995. In the context of increasing the piezoelectricity of the piezoelectric layer 240, x is preferably from 0.35 to 0.5, and y is preferably from 0.5 to 0.65. In practice, the values of x and y are determined as appropriate in the context of the crystallinity that can satisfy the required characteristics for the piezoelectric layer 240 and the required piezoelectricity for the piezoelectric layer 240. In the present embodiment, ScAlN having a composition of Sc_{0.2}Al_{0.8}N is mainly used.

### <Description of Hi-Pulse Sputtering Method>

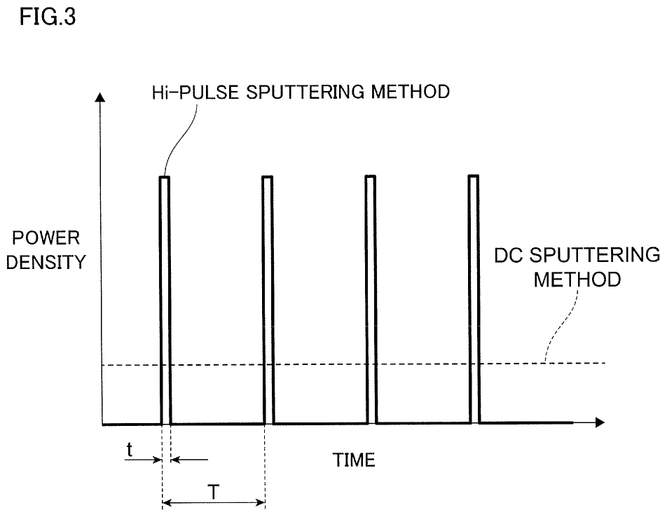

Referring to FIG. 3, a description will be given of a Hi-pulse sputtering method (High Power Impulse Magnetron Sputtering: HiPMS) used for forming the buffer layer 220 and the piezoelectric layer 240.

FIG. 3 shows the Hi-pulse sputtering method.

The Hi-pulse sputtering method periodically switches the pulse on and off, so that the power density observed in the Hi-pulse sputtering method has a periodic wave form as shown in FIG. 3. As shown, T represents a periodical interval at which the pulse is turned on in the Hi-pulse sputtering method, and t represents duration in which the pulse is on. The Hi-pulse sputtering method applies a voltage between the substrate 210 and a target in pulses. The method generates plasma from a sputtering gas introduced into a sputtering apparatus and causes ions generated in the plasma to collide with the target to thereby deposit components dislodged from the target onto the substrate 210 and form a film thereon.

Here, a duty ratio, which is the fraction of one period in which the pulse is kept on, is t/T. In the Hi-pulse sputtering method according to the present embodiment, it is preferred that the duty ratio be smaller.

With a smaller duty ratio, a higher electric current is applied at a time, which can produce an instantaneous high power density. An average power density during pulse application can be calculated from the following expression.

### [Expression 1]

$$( AVERAGE POWER DENSITY ) = \frac{\begin{matrix}( PULSE AVERAGE VOLTAGE ) \times \\ ( PULSE AVERAGE CURRENT )\end{matrix}}{( TARGET AREA )}$$

As shown by the above expression, the average power density can be obtained by dividing the product of a pulse average voltage and a pulse average current by a target area. Here, voltages and currents do not rise and fall vertically but exhibit misshapen square waveforms due to stray capacity and other factors. For this reason, average values of voltages and currents during time t when the pulse is on are used.

The pulse average voltage is a value that is obtained by dividing the time integral of the voltage applied during pulse application by time t when the pulse is on. The pulse average current is a value that is obtained by dividing the time integral of the current flowing during pulse application by time t when the pulse is on.

The average power density is higher than that in a sputtering method using constant voltages and currents, e.g., a normal DC sputtering method. The method of the present embodiment can instantaneously produce a high average power density, which facilitates increasing the collision energy with which the ions generated in the plasma collide with the target.

When the pulse is on, the method of the present embodiment can produce a higher collision energy than that in DC sputtering methods and increase ionization rates for the sputtering gas and the target.

When the pulse is off, the components of the target dislodged and deposited on the substrate 210 react with ions of the sputtering gas, and the crystal growth takes place on the substrate 210.

Below reference is made to results of measuring the crystallinity of the buffer layer 220 formed by the Hi-pulse sputtering method using single-crystalline sapphire as the substrate 210, Al as the target, and nitrogen (N₂) as the sputtering gas.

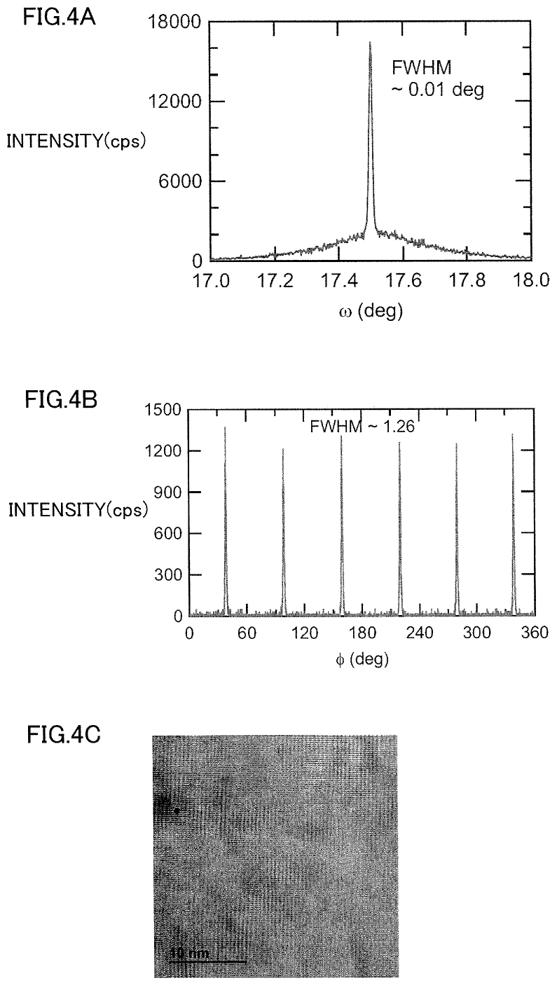

FIG. 4A shows a result of out of plane X-ray rocking curve (XRC) measurement for AlN according to the present embodiment. The Miller index of this measured surface of AlN is (0002). A smaller full width at half maximum (FWHM) of XRC corresponds to better crystallinity.

FIG. 4B shows a result of in-plane XRC measurement for AlN according to the present embodiment. The Miller index of this measured plane of AlN is (1-101). That is, this plane is inclined with respect to the surface of the AlN layer. A peak structure with peaks at 60 degrees intervals is observed. This peak structure reflects six-fold symmetry of single-crystalline AlN in in-plane asymmetric plane measurement. This peak structure with peaks at 60 degrees intervals is not observed in polycrystalline AlN. This indicates that AlN according to the present embodiment is single-crystalline.

It should be noted that although negative values are usually written with a bar above the number in the Miller index notation and the zone axis notation (described below), negative values are herein denoted with a negative sign (−) for convenience of description.

FIG. 4C shows a cross-sectional transmission electron microscope (TEM) image of AlN according to the present embodiment. As compared to polycrystalline AlN, fewer grain boundaries are observed. This indicates that AlN according to the present embodiment has excellent crystallinity.

### <Description of a Method for Manufacturing the Buffer Layer 220, the Electrode Layer 230, and the Piezoelectric Layer 240>

Now a description will be given of an exemplary method for manufacturing the buffer layer 220, the electrode layer 230, and the piezoelectric layer 240 on the substrate 210. The following description uses an example where single-crystalline sapphire is selected as the substrate 210 and Ru is selected as a main component of the electrode layer 230. In the present embodiment, the substrate 210, the buffer layer 220, the electrode layer 230, and the piezoelectric layer 240 can be viewed as an example of the laminate.

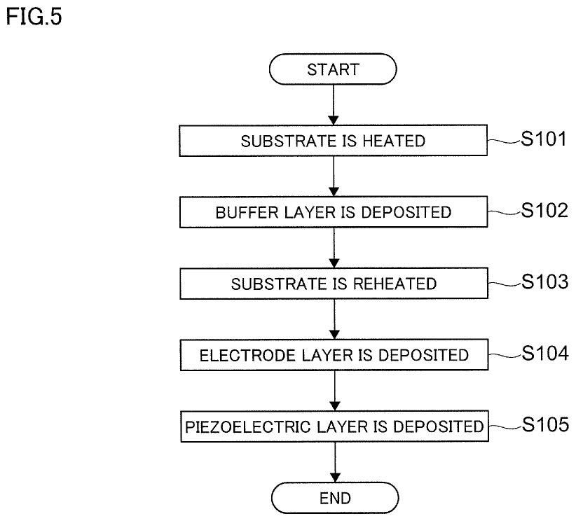

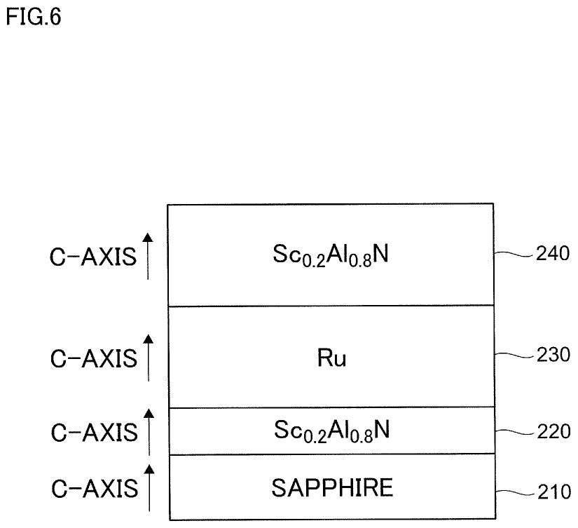

FIG. 5 is a flowchart of the exemplary method for manufacturing the buffer layer 220, the electrode layer 230, and the piezoelectric layer 240. FIG. 6 shows the buffer layer 220, the electrode layer 230, and the piezoelectric layer 240 deposited in this method.

First, the substrate 210, which is a single-crystalline sapphire substrate and has a c-plane surface, is loaded into the sputtering apparatus and heated to have moisture removed therefrom (step 101). For example, the substrate 210 is heated twice each for 30 seconds at 1000 W. During heating, the temperature of the substrate 210 reaches about 400 to 500° C.

Then, a thin film of Sc_{0.2}Al_{0.8}N is deposited as the buffer layer 220 on the substrate 210 (step 102). In the present embodiment, the Hi-pulse sputtering method is used to deposit the buffer layer 220. In this case, the target is Al containing 20% Sc, and a gas mixture of argon (Ar) and N₂ at a ratio of 1:1 is used as the sputtering gas. Also, a sputtering gas pressure is set to 0.73 Pa. A voltage between the substrate 210 and the target is set to 929 V, and an electric current is set to 2.5 A. As regards pulse conditions, a pulse width is set to 20 μs at 1000 Hz. That is, the duty ratio under these conditions is 2.0%. Components dislodged from the target react with nitrogen in a plasma state to produce Sc_{0.2}Al_{0.8}N. Preferably, the buffer layer 220 has a thickness of from 10 nm to 100 nm. If the buffer layer 220 has a thickness of less than 10 nm, island growth would occur, making it impossible to well cover the surface. On the other hand, if the buffer layer 220 has a thickness of more than 100 nm, dislocations or defects would be likely to occur. Since Al containing 20% Sc is used as the target, the film of Sc_{0.2}Al_{0.8}N is deposited. Varying the ratio of Sc and Al in the target can vary the ratio of Sc and Al in the ScAlN film deposited.

Table 1 shows a comparison between Sc_{0.2}Al_{0.8}N according to the present embodiment and Sc_{0.2}Al_{0.8}N deposited by a conventional DC sputtering method.

TABLE 1

| | AVERAGE | | | XRC |
|---|---|---|---|---|
| | POWER | | Pressure of | FWHM |
| Film Depositing | DENSITY | Sputtering | Sputtering | ScAIN |
| Method | (W/cm²) | Gas | Gas (Pa) | (0002) |
| Hi-pulse | 811 | Ar:N₂ = 1:1 | 0.73 | 0.14 |
| Sputtering Method | | | | |
| DC Sputtering Method | 5.0 | Ar:N₂ = 1:1 | 0.73 | 1.50 |

Sc_{0.2}Al_{0.8}N according to the present embodiment shown in Table 1 corresponds to the thin film deposited at step 102 and has a thickness of 100 nm. Sc_{0.2}Al_{0.8}N deposited by the DC sputtering method has a thickness of 100 nm.

The Miller index of the surface of Sc_{0.2}Al_{0.8}N as measured by XRC is (0002). The table shows that an FWHM of Sc_{0.2}Al_{0.8}N according to the present embodiment is 0.14° while that of Sc_{0.2}Al_{0.8}N deposited by the DC sputtering method is 1.50°.

At step 102, a thin film of AlN devoid of Sc may be deposited as the buffer layer 220 on the substrate 210, instead of the thin film of Sc_{0.2}Al_{0.8}N.

Table 2 shows a comparison between AlN according to the present embodiment and AlN deposited by a conventional DC sputtering method.

TABLE 2

| | AVERAGE | | | XRC |
|---|---|---|---|---|
| | POWER | Sputter- | Pressure of | FWHM |
| Film Depositing | DENSITY | ing | Sputtering | AIN |
| Method | (W/cm²) | Gas | Gas (Pa) | (0002) |
| Hi-pulse | 811 | N₂ | 0.73 | 0.09 |
| Sputtering Method | | | | |
| DC Sputtering Method | 5.0 | N₂ | 0.73 | 1.26 |

In this case, the target is Al, and N₂ is used as the sputtering gas. Also, a sputtering gas pressure is set to 0.73 Pa, for example. Components dislodged from the target react with N₂ on the substrate 210 to produce AlN.

AlN according to the present embodiment corresponds to the thin film deposited at step 102 and has a thickness of 100 nm. AlN deposited by the DC sputtering method has a thickness of 100 nm.

The Miller index of the surface of AlN as measured by XRC is (0002). The table shows that an FWHM of AlN according to the present embodiment is 0.09° while that of AlN deposited by the DC sputtering method is 1.26°.

Then, the substrate 210 with the buffer layer 220 deposited thereon is reheated (step 103). For example, the substrate 210 is heated once for 30 seconds at 1000 W. During heating, the temperature of the substrate 210 reaches about 400 to 500° C. This improves crystallinity of the electrode layer 230 during the subsequent formation of the electrode layer 230.

Then, a thin film of Ru is deposited as the electrode layer 230 on the buffer layer 220 (step 104). At this time, in the present embodiment, a normal DC sputtering method is used, rather than the Hi-pulse sputtering method. A target made of Ru is used, and Ar is used for a sputtering gas. Pressure of the sputtering gas is set to, for example, 0.5 Pa, and the sputtering is conducted at 1000 W. Preferably, the electrode layer 230 has a thickness of from 10 nm to 1000 nm. If the electrode layer 230 has a thickness of less than 10 nm, the electrode layer 230 might not function well as an electrode. On the other hand, if the electrode layer 230 has a thickness of more than 1000 nm, it has almost the same thickness as the piezoelectric layer, which may adversely affect the piezoelectricity.

Further, a thin film of Sc_{0.2}Al_{0.8}N is deposited as the piezoelectric layer 240 on the electrode layer 230 (step 105). At this time, in the present embodiment, the Hi-pulse sputtering method is used to deposit the piezoelectric layer 240 using the target containing Al and Sc. The sputtering conditions are the same as those at step 102, but the deposition takes several hours. At this time, the temperature of the substrate 210 settles at about 200 to 350° C. The piezoelectric layer 240 is formed on the entire surface of the electrode layer 230. Preferably, the piezoelectric layer 240 has a thickness of from 10 nm to 5000 nm.

Table 3 shows relationship between the duty ratio of the Hi-pulse sputtering method for the deposition of the piezoelectric layer 240, the average power density during pulse application, and the crystallinity of Sc_{0.2}Al_{0.8}N according to the present embodiment.

TABLE 3

| | | | AVERAGE | | | XRC |
|---|---|---|---|---|---|---|
| Duty | | Pulse | POWER | Sputter- | Pressure of | FWHM |
| Ratio | Frequency | Width | DENSITY | ing Gas | Sputtering | ScAIN |
| (%) | (Hz) | (μs) | (W/cm²) | Ar:N₂ | Gas (Pa) | (0002) |
| 4.0 | 1000 | 40 | 2439 | 1:1 | 0.73 | 3.51 |
| 3.5 | 1000 | 35 | 1936 | 1:1 | 0.73 | 2.34 |
| 3.0 | 1000 | 30 | 1427 | 1:1 | 0.73 | 1.94 |
| 2.5 | 1000 | 25 | 956 | 1:1 | 0.73 | 1.35 |
| 2.0 | 1000 | 20 | 811 | 1:1 | 0.73 | 0.99 |
| 1.5 | 1000 | 15 | 677 | 1:1 | 0.73 | 1.02 |
| 1.0 | 1000 | 10 | 247 | 1:1 | 0.73 | 2.43 |

Sc_{0.2}Al_{0.8}N according to the present embodiment shown in Table 3 corresponds to the thin film deposited at step 105 and has a thickness of 1000 nm. Ru (with a thickness of 100 nm) is used for the electrode layer 230, and Sc_{0.2}Al_{0.8}N (with a thickness of 50 nm) is used for the buffer layer 220.

Sc_{0.2}Al_{0.8}N was deposited as the piezoelectric layer 240 on the electrode layer 230 using the Hi-pulse sputtering method at duty ratios of 4.0%, 3.5%, 3.0%, 2.5%, 2.0%, 1.5%, and 1.0%. At a duty ratio of more than 4.0%, the crystallinity would be likely to degrade. At a duty ratio of less than 0.5%, the deposition rate would be so slow as to make it difficult to deposit the film.

Sc_{0.2}Al_{0.8}N was deposited as the piezoelectric layer 240 using the Hi-pulse sputtering method at average power densities during pulse application of 2439 W/cm², 1936 W/cm², 1427 W/cm², 956 W/cm², 811 W/cm², 677 W/cm², and 247 W/cm².

The Miller index of the surface of Sc_{0.2}Al_{0.8}N as measured by XRC is (0002). An FWHM of Sc_{0.2}Al_{0.8}N deposited at the duty ratio of 4.0% is 3.51°. Reducing the duty ratio from 4.0% to 2.0% improves the FWHM of Sc_{0.2}Al_{0.8}N from 3.51° to 0.99°. The duty ratio of the Hi-pulse sputtering method to deposit Sc_{0.2}Al_{0.8}N is preferably not more than 4.0%, more preferably not more than 3.5%, yet more preferably not more than 3.0%, yet still more preferably not more than 2.5%, and yet even still more preferably not more than 2.0%.

If the average power density in depositing Sc_{0.2}Al_{0.8}N according to the present embodiment is low, the collision energy might not be sufficiently high. The FWHM of Sc_{0.2}Al_{0.8}N deposited at the average power density of 2439 W/cm² is 3.51°. The FWHM of Sc_{0.2}Al_{0.8}N deposited at the average power density of 247 W/cm² is 2.43°. The average power density during pulse application in the Hi-pulse sputtering method to deposit Sc_{0.2}Al_{0.8}N is preferably from 200 W/cm² to 2500 W/cm². Increasing the average power density from 247 W/cm² to 811 W/cm² improves the FWHM of Sc_{0.2}Al_{0.8}N from 2.43° to 0.99°. The average power density during pulse application in the Hi-pulse sputtering method to deposit Sc_{0.2}Al_{0.8N} is more preferably from 600 W/cm² to 2500 W/cm², and yet more preferably from 800 W/cm² to 2500 W/cm². Reducing the average power density from 2439 W/cm² to 811 W/cm² improves the FWHM of Sc_{0.2}Al_{0.8}N from 3.51° to 0.99°. The average power density during pulse application in the Hi-pulse sputtering method to deposit Sc_{0.2}Al_{0.8}N is more preferably not more than 2000 W/cm², yet more preferably not more than 1500 W/cm², and yet still more preferably not more than 1000 W/cm².

Table 4 shows relationship between the duty ratio of the Hi-pulse sputtering method for the deposition of the piezoelectric layer 240, the average power density, and the crystallinity of AlN according to the present embodiment.

TABLE 4

| | | | AVERAGE | | | XRC |
|---|---|---|---|---|---|---|
| Duty | | Pulse | POWER | | Pressure of | FWHM |
| Ratio | Frequency | Width | DENSITY | Sputter- | Sputtering | AIN |
| (%) | (Hz) | (μs) | (W/cm²) | ing Gas | Gas (Pa) | (0002) |
| 4.0 | 1000 | 40 | 2439 | N₂ | 0.73 | 1.62 |
| 3.5 | 1000 | 35 | 1936 | N₂ | 0.73 | 1.34 |
| 3.0 | 1000 | 30 | 1427 | N₂ | 0.73 | 1.17 |
| 2.5 | 1000 | 25 | 956 | N₂ | 0.73 | 1.12 |
| 2.0 | 1000 | 20 | 811 | N₂ | 0.73 | 1.04 |
| 1.5 | 1000 | 15 | 677 | N₂ | 0.73 | 1.44 |
| 1.0 | 1000 | 10 | 247 | N₂ | 0.73 | 1.55 |

AlN according to the present embodiment shown in Table 4 corresponds to the thin film deposited at step 105 and has a thickness of 1000 nm. Ru (with a thickness of 100 nm) is used for the electrode layer 230, and AlN (with a thickness of 50 nm) is used for the buffer layer 220.

AlN was deposited as the piezoelectric layer 240 on the electrode layer 230 using the Hi-pulse sputtering method at duty ratios of 4.0%, 3.5%, 3.0%, 2.5%, 2.0%, 1.5%, and 1.0%. At a duty ratio of more than 4.0%, the crystallinity would be likely to degrade. At a duty ratio of less than 0.5%, the deposition rate would be so slow as to make it difficult to deposit the film.

AlN was deposited as the piezoelectric layer 240 using the Hi-pulse sputtering method at average power densities during pulse application of 2439 W/cm², 1936 W/cm², 1427 W/cm², 956 W/cm², 811 W/cm², 677 W/cm², and 247 W/cm².

The Miller index of the surface of AlN as measured by XRC is (0002). An FWHM of AlN deposited at the duty ratio of 4.0% is 1.62°. Reducing the duty ratio from 4.0% to 2.0% improves the FWHM of AlN from 1.62° to 1.04°. The duty ratio of the Hi-pulse sputtering method to deposit AlN is preferably not more than 4.0%, more preferably not more than 3.5%, yet more preferably not more than 3.0%, yet still more preferably not more than 2.5%, and yet even still more preferably not more than 2.0%.

If the average power density in depositing AlN according to the present embodiment is low, the collision energy might not be sufficiently high. The FWHM of AlN deposited at the average power density of 2439 W/cm² is 1.62°. The FWHM of AlN deposited at the average power density of 247 W/cm² is 1.55°. The average power density during pulse application in the Hi-pulse sputtering method to deposit AlN is preferably from 200 W/cm² to 2500 W/cm². Increasing the average power density from 247 W/cm² to 811 W/cm² improves the FWHM of AlN from 1.55° to 1.04°. The average power density during pulse application in the Hi-pulse sputtering method to deposit AlN is more preferably not less than 600 W/cm², and yet more preferably not less than 800 W/cm². Also, reducing the average power density from 2439 W/cm² to 811 W/cm² improves the FWHM of AlN from 1.62° to 1.04°. The average power density during pulse application in the Hi-pulse sputtering method to deposit AlN is more preferably not more than 2000 W/cm², yet more preferably not more than 1500 W/cm², and yet still more preferably not more than 1000 W/cm².

In the above example, both of the buffer layer 220 and the piezoelectric layer 240 are made of Sc_{0.2}Al_{0.8}N or AlN. Preferably, both of the buffer layer 220 and the piezoelectric layer 240 are made of ScAlN or AlN. That is, preferably, the buffer layer 220 and the piezoelectric layer 240 have the same composition. This eliminates the need for replacing the target. Alternatively, one of the buffer layer 220 and the piezoelectric layer 240 may be made of ScAlN and the other may be made of AlN. This, however, requires replacement of the target.

Now a description will be given of the crystallinity of the piezoelectric layer 240 according to the present embodiment.

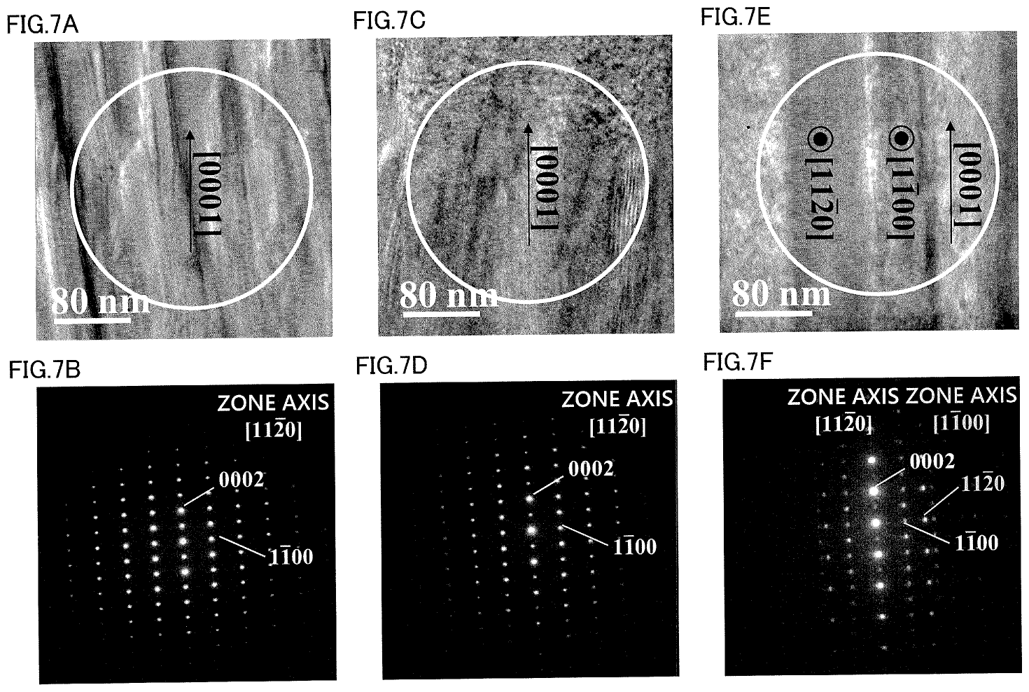

FIG. 7A shows a TEM image of AlN according to the present embodiment. The upward direction in the figure corresponds to the crystal growth direction, and AlN has the [0001] crystallographic axis.

FIG. 7B shows an electron diffraction pattern of AlN according to the present embodiment. This electron diffraction pattern was obtained by electron beam irradiation of a portion within the circle of FIG. 7A. The diameter of the electron beam as represented by this circle is about 200 nm.

As shown in FIG. 7B, in terms of the Miller indices, the (0002) plane and the (1-100) plane are observed in AlN according to the present embodiment. In this case, only the zone axis [11-20] is present. In other words, only one zone axis is observed as the electron diffraction pattern. This means that AlN according to the present embodiment is a single crystal substance with excellent crystallinity. Also, AlN according to the present embodiment can be said to have a triaxial orientation as it is c-axis oriented with the ab in-plane rotations controlled. In this case, AlN consists of columnar domains of a single kind extending in the c-axis direction with rotational directions aligned in the ab plane.

FIG. 7C shows a TEM image of Sc_{0.2}Al_{0.8}N according to the present embodiment. As with the above example, the upward direction in the figure corresponds to the crystal growth direction, and Sc_{0.2}Al_{0.8}N has the [0001] crystallographic axis.

FIG. 7D shows an electron diffraction pattern of Sc_{0.2}Al_{0.8}N according to the present embodiment. As shown in FIG. 7D, in terms of the Miller indices, the (0002) plane and the (1-100) plane are observed in Sc_{0.2}Al_{0.8}N according to the present embodiment. In this case, only the [11-20] zone axis is present. In other words, in this case too, only one zone axis is observed as the electron diffraction pattern. This means that Sc_{0.2}Al_{0.8}N according to the present embodiment is a single crystal substance with excellent crystallinity. In other words, Sc_{0.2}Al_{0.8}N according to the present embodiment can be said to also have a triaxial orientation. In this case, Sc_{0.2}Al_{0.8}N consists of columnar domains of a single kind extending in the c-axis direction with rotational directions aligned in the ab plane.

FIG. 7E shows a TEM image of polycrystalline AlN. As with the above examples, the upward direction in the figure corresponds to the crystal growth direction, and AlN has the [0001] crystallographic axis.

FIG. 7F shows an electron diffraction pattern of polycrystalline AlN. As shown in FIG. 7F, in terms of the Miller indices, the (11-20) plane in addition to the (0002) plane and the (1-100) plane are observed in polycrystalline AlN. In this case, two zone axes of [11-20] and [1-100] are present. That is, in this case, two zone axes are observed as the electron diffraction pattern. This demonstrates that this AlN is polycrystalline. FIG. 7E shows portions where the [11-20] and [1-100] zone axes are observed. That is, this AlN is c-axis oriented but does not have the ab in-plane rotations controlled. In this case, the AlN consists of columnar domains of two different kinds rotated by 30° with respect to each other in the ab plane and extending in the c-axis direction.

### <Electrode Layer 230>

In the above example, Ru is used for the electrode layer 230, but this is not limiting. However, metals that can be used for the electrode layer 230 are required to ensure that the piezoelectric layer 240 with excellent crystallinity can be formed on the electrode layer 230. Since AlN or ScAlN constituting the piezoelectric layer 240 is hexagonal system, any hexagonal system metal, when used for the electrode layer 230, will ensure that the piezoelectric layer 240 with excellent crystallinity can be formed on the electrode layer 230. For example, when sputtering is used to form the piezoelectric layer 240 on the electrode layer 230, the hexagonal AlN (0001) plane or ScAlN (0001) plane epitaxially grow on the (0001) plane of the metal that is hexagonal system as well. That is, the growth plane of AlN and ScAlN is the (0001) plane. Put other ways, the growth plane of AlN and ScAlN is the c-plane, and they grow in the c-axis direction.

In the case of using any cubic system metal, on the other hand, a difference in lattice constants between the electrode layer 230 and the piezoelectric layer 240 can be problematic. In this case, it is required that a lattice mismatch between the electrode layer 230 and ScAlN or AlN constituting the piezoelectric layer 240 be in a range from −25% to 2%. In this case, the hexagonal AlN (0001) plane or ScAlN (0001) plane grow on the fcc (111) plane ((111) plane of the face-centered cubic lattice) or the bcc (110) plane ((110) plane of the body-centered cubic lattice) of the cubic system metal.

A lattice mismatch can be expressed as Δx/x, which represents a ratio of a difference Δx between interatomic distances of the electrode layer 230 and the piezoelectric layer 240 to the interatomic distance x of the electrode layer 230. When this value is small, the piezoelectric layer 240 can be formed on the electrode layer 230 even with the presence of a lattice mismatch. For example, when sputtering is used to form the piezoelectric layer 240 on the electrode layer 230, the thin film of the piezoelectric layer 240 can be epitaxially grown on the electrode layer 230. In this case, the crystal lattice of AlN or ScAlN constituting the piezoelectric layer 240 is distorted on the electrode layer 230, which causes the piezoelectric layer 240 to epitaxially grow while preserving lattice continuity at the interface between these layers.

The lattice mismatch may be a simple ratio of the lattice constants of the electrode layer 230 and the piezoelectric layer 240 when both of them have a hexagonal crystal structure. When, on the other hand, the electrode layer 230 has a cubic crystal structure and the piezoelectric layer 240 has a hexagonal crystal structure, a three-dimensional view should be taken.

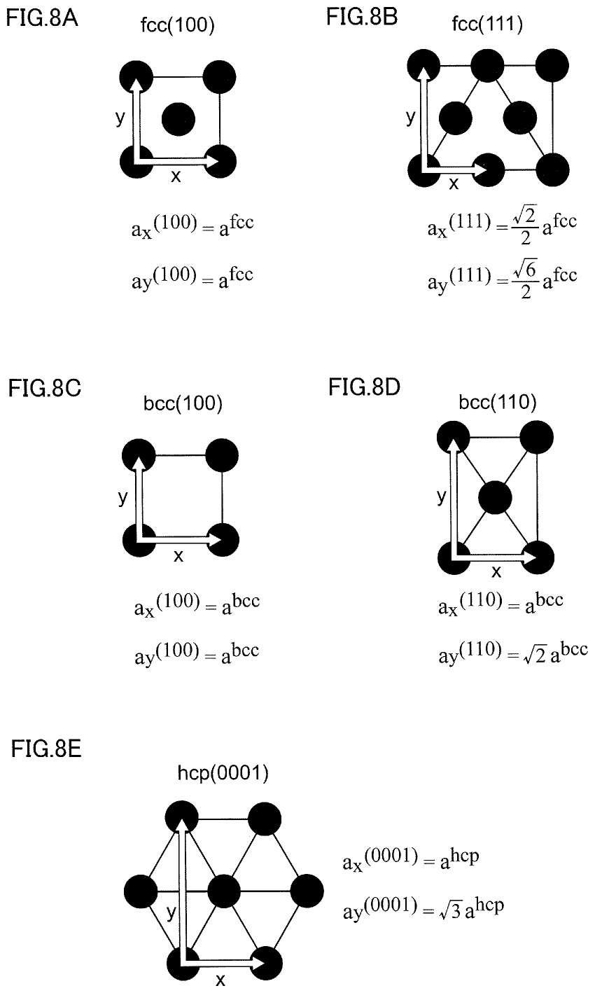

FIGS. 8A-8E each show the interatomic distance x used to calculate the lattice mismatch.

FIG. 8A shows a cubic fcc (100) plane, and FIG. 8B shows a cubic fcc (111) plane. In the case of FIG. 8A, based on the lattice constant being a^{fcc}, x is aₓ⁽¹⁰⁰⁾=a^{fcc}, so that the lattice constant a^{fcc} can be directly used. In the case of FIG. 8B, on the other hand, based on the lattice constant being a^{fcc}, x is aₓ⁽¹¹¹⁾=(√2/2)a^{fcc}, so that the lattice constant a^{fcc} cannot be directly used. Thus, when the hexagonal AlN (0001) plane or ScAlN (0001) plane is to be grown on the fcc (111) plane of a cubic metal, the lattice constant a^{fcc} cannot be directly used, and (√2/2)a^{fcc} is used as the interatomic distance x.

FIG. 8C shows a cubic bcc (100) plane, and FIG. 8D shows a cubic bcc (110) plane. In the case of FIG. 8C, based on the lattice constant being a^{bcc}, x is aₓ⁽¹⁰⁰⁾=a^{bcc}, so that the lattice constant a^{bcc} can be directly used. In the case of FIG. 8D, based on the lattice constant being a^{bcc}, x is aₓ⁽¹¹⁰⁾=a^{bcc}, so that the lattice constant a^{bcc} can be directly used too. Thus, when the hexagonal AlN (0001) plane or ScAlN (0001) plane is to be grown on the bcc (110) plane of a cubic metal, the lattice constant abcc can be directly used as the interatomic distance x.

FIG. 8E shows a hexagonal (0001) plane. In the case of FIG. 8E, based on the lattice constant being a^{hcp}, x is aₓ⁽⁰⁰⁰¹⁾=a^{hcp}, so that the lattice constant a^{hcp} can be directly used. Thus, when the hexagonal AlN (0001) plane or ScAlN (0001) plane is to be grown on the (0001) plane of a hexagonal metal, the lattice constant a^{hcp} can be directly used as the interatomic distance x.

However, in actual crystal systems, an interatomic distance y is also present as shown in each of FIGS. 8A to 8E. In one example, in the case of the cubic bcc (110) plane shown in FIG. 8D, y=√2x. In another example, in the case of the hexagonal (0001) plane shown in FIG. 8E, y=√3x. Thus, during the actual epitaxial growth, x values match, but y values do not match, so that the lattice distortion is occurring. That is, the interatomic distance x refers to a distance between the closest atoms in the respective planes of the electrode layer 230 and the piezoelectric layer 240 at which they adjoin each other.

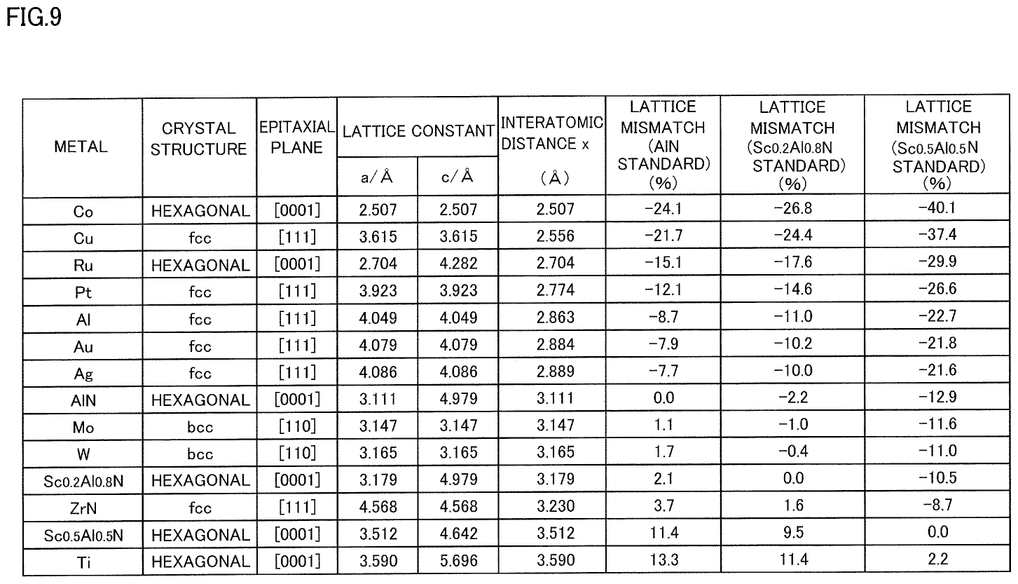

FIG. 9 is a table showing specific examples of lattice mismatches between the electrode layer 230 and the piezoelectric layer 240.

FIG. 9 lists the kinds of materials (denoted as “metal”) constituting the electrode layer 230, their crystal structures, epitaxial growth planes, lattice constants, interatomic distances x, and lattice mismatches. As regards the crystal structures, “fcc” and “bcc” represent cubic system, and “hexagonal” represents hexagonal system. The table shows three different lattice mismatches, namely with respect to AlN, Sc_{0.2}Al_{0.8}N, and Sc_{0.5}Al_{0.5}N. The table also lists AlN, Sc_{0.2}Al_{0.8}N, Sc_{0.5}Al_{0.5}N, and ZrN, as well as metals. Preferably, the material constituting the electrode layer 230 is chosen from those that ensure that an FWHM of an X-ray rocking curve (XRC) of the (0002) plane of the piezoelectric layer 240 is not more than 2.5°. In other words, an XRC FWHM of not more than 2.5° will provide excellent crystallinity, but an XRC FWHM of more than 2.5° will not provide excellent crystallinity.

In this context, when the composition ScₓAl_{y}N (x+y=1) representing AlN or ScAlN satisfies 0≤x≤0.3, it is preferred that the material constituting the electrode layer 230 include at least one substance selected from Co, Cu, Ru, Pt, Al, Au, Ag, Mo, W, ZrN, and Ti. Also, when the composition ScₓAl_{y}N (x+y=1) representing AlN or ScAlN satisfies 0.3<x≤0.5, it is preferred that the material constituting the electrode layer 230 include at least one substance selected from Co, Ru, Al, Au, Ag, Mo, W, ZrN, and Ti. These may be used alone, or alloys thereof may also be used.

### <Substrate 210>

In the above example, sapphire is used for the substrate 210, but this is not limiting. Nevertheless, it is preferred that use be made of a substrate that has any composition selected from sapphire, Si, quartz, SrTiO₃, LiTaO₃, LiNbO₃, and SiC. The substrate 210 with such a composition further facilitates epitaxial growth thereon of the buffer layer 220 made of AlN or ScAlN.

In addition, the substrate 210 may be replaced. For example, a sapphire substrate is used to form the buffer layer 220, the electrode layer 230, and the piezoelectric layer 240, and then the sapphire substrate is released and the layers formed are moved and bonded to another substrate, which is for example an Si substrate. A method for manufacturing the resonator 100 involving releasing of the substrate 210 will be detailed in subsequent paragraphs.

### <Description of a Method for Manufacturing the Resonator 100>

Now a description will be given of a method for manufacturing the resonator 100 using the laminate 200.

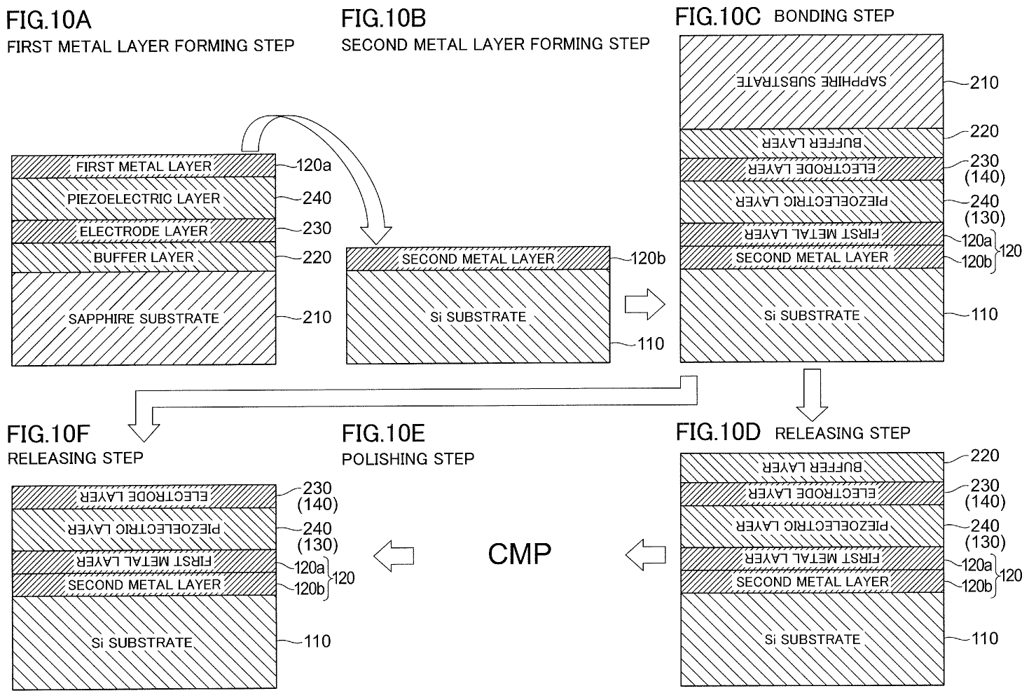

FIGS. 10A to 10F show a method for manufacturing the resonator 100.

First, the laminate 200 is formed by the method described with reference to FIG. 5 (a laminate forming step).

Then, as shown in FIG. 10A, a first metal layer is formed on the laminate 200. The first metal layer can be formed by sputtering. The first metal layer forms a part of the lower electrode layer 120 (see FIG. 1). In FIG. 10A, this first metal layer is denoted as a lower electrode layer 120a to indicate that it is a part of the lower electrode layer 120. Hence, this step can be viewed as a first metal layer forming step of forming the first metal layer (lower electrode layer 120a) containing a metal on the laminate 200.

Then, as shown in FIG. 10B, a second metal layer is formed on the substrate 110. Similarly to the first metal layer, the second metal layer can be formed by sputtering. The second metal layer forms a part of the lower electrode layer 120 (see FIG. 1). In FIG. 10B, this second metal layer is denoted as a lower electrode layer 120b to indicate that it is a part of the lower electrode layer 120. Hence, this step can be viewed as a second metal layer forming step of forming the second metal layer on another substrate 110 different from the substrate 210 (denoted as “sapphire substrate” in FIG. 10A). As previously described with reference to FIG. 1, the substrate 110 is a support substrate, and a silicon (Si) single-crystalline substrate is used therefor (denoted as “Si substrate” in FIG. 10B). Ru, Au, Ag, Cu, Pt, Al, Mo, W, and the like may be used for the lower electrode layers 120a, 120b.

Then, as shown in FIG. 10C, a top surface of the laminate 200 with the first metal layer (lower electrode layer 120a) formed thereon is bonded to a top surface of the substrate 110 with the second metal layer (lower electrode layer 120b) formed thereon. Hence, this step can be viewed as a bonding step of bonding the first metal layer (lower electrode layer 120a) formed on the laminate 200 to the second metal layer (lower electrode layer 120b) on the substrate 110. For example, the bonding of these layers is performed by a joining machine that applies heat and pressure to join them.

As shown in FIG. 10C, this results in a joined body formed by lamination of the substrate 110, the lower electrode layer 120b, the lower electrode layer 120a, the piezoelectric layer 240 (piezoelectric layer 130), the electrode layer 230 (upper electrode layer 140), the buffer layer 220, and the substrate 210. The lower electrode layer 120a and the lower electrode layer 120b can be collectively viewed as the lower electrode layer 120.

Then, the substrate 210 and the buffer layer 220 are released from the laminate 200 (releasing step). For example, the releasing may be performed with pulsed high-density ultraviolet (UV) laser light emitted from a laser lift-off apparatus.

In this step, both of the substrate 210 and the buffer layer 220 may be released at a time as shown in FIG. 10F.

As shown in FIG. 10D, on the other hand, at least a portion of the buffer layer 220 may be left unreleased. In the case of FIG. 10D, the residual buffer layer 220 is removed by chemical mechanical polishing (CMP) shown in FIG. 10E. This results in the state shown in FIG. 10F. In this case, the step includes releasing the substrate 210 and then releasing the buffer layer 220.

Through these steps, the resonator 100 formed by lamination of the substrate 110, the lower electrode layer 120, the piezoelectric layer 130, and the upper electrode layer 140 can be manufactured as shown in FIG. 10F.

The embodiment detailed above provides the piezoelectric layer 240 with excellent crystallinity. In other words, the above embodiment provides the single-crystalline piezoelectric layer 240.

Ensuring excellent crystallinity of the piezoelectric layer 240 holds promise for manufacturing a resonator or a high-frequency filter that can function as a filter having a high Q value and a wide bandwidth. In other words, while conventional filters have a tradeoff between a high Q value and a wide bandwidth, filters of the present embodiment are expected to achieve both of these characteristics.

Ensuring excellent crystallinity of the piezoelectric layer 240 also leads to fewer grain boundaries and low-loss characteristics. This, in turn, facilitates achieving a high Q value. In addition, the laminate of the present embodiment is epitaxially grown on the substrate 210, which is likely to lead to low-loss characteristics and achieving a high Q value as well. Further, the laminate of the present embodiment has high thermal conductivity and excellent voltage resistance. For this reason, the laminate has good heat dissipating properties and can be used as a filter for base stations with output power of 10 W or more. The laminate can also be expected to have longer life.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A method for manufacturing an AlN-based laminate, the method comprising:
forming on or above a substrate a single-crystalline electrode layer containing a metal element; and
forming an AlN-based piezoelectric layer on the electrode layer by sputtering, wherein
the forming the piezoelectric layer includes applying a pulse voltage to a target during the sputtering at a duty ratio of not more than 4% and at an average power density during pulse application of from 200 W/cm² to 2500 W/cm².

2. The method for manufacturing a laminate according to claim 1, wherein the duty ratio is not more than 2% during the sputtering.

3. The method for manufacturing a laminate according to claim 1, wherein the piezoelectric layer contains Sc.

4. The method for manufacturing a laminate according to claim 3, wherein a content of Sc in the piezoelectric layer is not more than 50 atomic %, based on a total of the number of Sc atoms and the number of Al atoms in the piezoelectric layer being taken as 100 atomic %.

5. The method for manufacturing a laminate according to claim 3, wherein the piezoelectric layer is formed using a target containing Al and Sc.

6. The method for manufacturing a laminate according to claim 1, wherein the piezoelectric layer is formed on an entire surface of the electrode layer.

7. The method for manufacturing a laminate according to claim 1, wherein the electrode layer has a composition including at least one substance selected from Co, Cu, Ru, Pt, Al, Au, Ag, Mo, W, ZrN, and Ti.

8. The method for manufacturing a laminate according to claim 1, wherein the substrate has any composition selected from sapphire, Si, quartz, SrTiO₃, LiTaO₃, LiNbO₃, and SiC.

9. The method for manufacturing a laminate according to claim 1, wherein the electrode layer with the piezoelectric layer laminated thereon is released from the substrate.
